(19) United States
(12) Patent Application Publication
(10) Pub. No.: US 2006/0172469 A1
(43) Pub. Date: Aug. 3, 2006

(54) Method of fabricating a polycrystalline silicon thin film transistor

(76) Inventors: Jia-Xing Lin, Panchiao City (TW); Yu-Cheng Chen, Hsinchu City (TW); Chi-Lin Chen, Hsinchu City (TW)

Correspondence Address: RABIN & BERDO, P.C., Suite 500, 1101 14 Street, N.W., Washington, DC, 20005, US

(21) Appl. No.: 11/312,473

(22) Filed: Dec. 21, 2005

(30) Foreign Application Priority Data
Feb. 1, 2005 (TW) 94103127

(51) Int. Cl. H01L 21/84; H01L 21/20

(52) U.S. Cl. 438/149; 438/486; 438/490

(57) ABSTRACT

An amorphous silicon (a-Si) layer is first formed on a substrate, and the a-Si layer is next patterned to form silicon islands for defining device active regions. Then, a single shot laser beam with long pulse is utilized to irradiate each silicon island, and lateral growth crystallization is induced in each silicon island for transforming a-Si into polycrystalline silicon (poly-Si). Finally, the general subsequent processes for thin film transistor (TFT) fabrication are performed in turn to fabricate poly-Si TFTs.

### RELATED APPLICATIONS

The present application is based on, and claims priority from, Taiwan Application Serial Number 94103127, filed Feb. 1, 2005, the disclosure of which is hereby incorporated by reference herein in its entirety.

### BACKGROUND OF THE INVENTION

1. Field of Invention

The present invention relates to a method of fabricating a polycrystalline silicon (poly-Si) thin film transistor (TFT), and more particularly, to a method of fabricating poly-Si with regularly distributed lateral growth grains for applying in the manufacturing of large-size TFT displays.

2. Related Art

Polycrystalline silicon (poly-Si) has superior electrical properties over amorphous silicon (a-Si) and the advantage of a lower cost than single crystalline silicon. It has attracted considerable attention in thin film transistors (TFTs) fabrication lately, and more particularly in the TFT liquid crystal display (TFT-LCD) fabrication.

However, the carrier mobility and device performance both are affected significantly by the crystal grain size of poly-Si. Therefore, in order to improve the device performance, it is very important to enlarge the grain size of poly-Si. For TFT-LCD technology, fabricating TFT with higher device performance for developing superior flat panel display (FPD) is the present technical target. The conventional methods for fabricating poly-Si comprises solid phase crystallization (SPC) and direct chemical vapor phase deposition (CVD), but those techniques are not applicable to high performance flat panel displays because the crystalline quality is limited by the low process temperature (typically lower than 650° C.), and the grain size of polycrystalline silicon is as small as 100 nm. Hence, the electrical characteristics of polycrystalline silicon thin film are limited.

The excimer laser annealing (ELA) method is currently the most commonly used method in poly-Si TFT fabrication. The grain size of poly-Si thin film can reach 300-600 nm, and the carrier mobility of poly-Si TFTs can reach 200 cm²/V-s. However, this carrier mobility is not sufficient for future demand of high performance FPDs. Moreover, the present ELA techniques require frequently repeated irradiation to re-melt imperfect fine grains caused by the irregular laser energy fluctuation and unstable laser energy output, and uniformity of grain size distribution is also be improved simultaneously.

The uniformity of ELA poly-Si TFT device performance, such as carrier mobility, threshold voltage and sub-threshold swing between devices are affected directly by poly-Si grain size deviation therefore, the picture quality of large-area ELA poly-Si driven FPD is degraded. Moreover, frequently repeated laser irradiation makes ELA less competitive and disadvangeous for large size FPD fabrication due to its high cost in process optimization and system maintenance, besides, product yield is also decreased.

### SUMMARY OF THE INVENTION

An object of the invention is to provide a method of fabricating a poly-Si TFT, and a poly-Si film with lateral growth crystallization is formed, besides, the poly-Si has high grain order and uniform grain size distribution. Therefore, the electrical performance of the TFT is greatly enhanced. The invention utilizes the pre-patterned a-Si island and single-shot laser beam with a long pulse to control the location of crystal lateral growth inside the a-Si island for forming a poly-Si film.

According to the aforementioned objectives of the present invention, a method of fabricating a poly-Si TFT is provided. According to a preferred embodiment of the invention, an a-Si layer is first formed on a substrate, and the a-Si layer is then patterned to form a-Si islands on the substrate for defining device active regions. Wherein, the material of the substrate is glass. Next, a single shot laser beam with a long pulse is utilized to irradiate each a-Si island for inducing lateral growth crystallization occurred along a-Si island edges, and a-Si is thus transformed into poly-Si.

Each a-Si island is a rectangular strip structure. Therefore, cooling occurs gradually in melted a-Si island from the long side toward the inside of each a-Si island after laser irradiation, and lateral crystallization growth is then occurred along the long side of each melted a-Si island edge, toward the inside of each a-Si island after cooling. Finally, poly-Si with lateral growth crystallization and high grain order is obtained.

The single-shot laser beam with a long pulse utilizes an ultraviolet excimer laser pulse, for example, xenon chloride XeCl laser pulse. Moreover, the laser beam has a pulse duration of about 100˜300 ns in order to lengthen the melting time of a-Si for crystallization, and lateral crystallization growth is thus further enhanced.

Besides, a buffer layer can be further formed on the substrate before forming the a-Si layer in order to prevent device fabrication from being contaminated by substrate. Moreover, the general TFT fabrication process (e.g. gate oxide formation, gate metal fabrication, ion implantation, dielectric interlayer formation, contact holes definition, and source/drain metal fabrication) can be directly used to fabricate the poly-Si TFT devices after transforming the a-Si layer into the poly-Si layer by laser irradiation.

Furthermore, each a-Si island for defining device active regions has a channel region, a source region, and a drain region; wherein the channel region in the a-Si island can be a single rectangular strip structure or has a plurality of rectangular strip structures. The device active region is a multi-channel structure design if the channel region has a plurality of rectangular strip structures. Besides, each short side of the rectangular strip structures connecting the source region or the drain region is shorter than a double of a grain lateral crystallization growth length in order to well control grain location and lateral crystallization growth direction inside each channel region regularly, and poly-Si with high grain order and uniform grain size distribution is thus formed.

According to the aforementioned method, the general step of defining device active region is carried out before laser irradiation. Therefore, a temperature gradient is natively formed inside each a-Si island after laser irradiation, and grain lateral crystallization growth is then occurred regularly along the island edge in each a-Si island. More particularly, the laser beam with a long pulse is utilized to enable more heat to be transmitted below a-Si for lengthening the melting time of a-Si for crystallization, and uniformity of laser energy distribution inside each a-Si island is further improved. Thus, not only grain size of crystallization is enlarged obviously, but also irregular laser energy transmission and poor laser energy distribution are mitigated. Finally, uniform lateral growth crystallization is produced in each a-Si island for forming poly-Si with uniform and large grain size. Consequently, a single shot laser beam is sufficient in the present invention to achieve a high quality poly-Si crystallization. Hence the process running cost of laser irradiation can be greatly reduced, and the fabrication of large-size FPD with poly-Si TFTs is able to be achieved. In conventional laser irradiation process for poly-Si crystallization a laser beam with a short pulse is normally utilized. It's difficult to induce sufficient lateral crystallization growth in silicon film, besides, the high temperature ramp in a short time will make a mass flow of the melted a-Si island, so that the island shrinkage issue may be frequently encountered during crystallization. Thus, the device active region feature size is not correctly defined, and TFT device performance and uniformity is degraded. In order to overcome the above problem, a laser beam with a long pulse is particularly disclosed in the present invention to be used for laser irradiation, and island patterns can be thus kept well after crystallization.

By employing the present invention, poly-Si TFT devices with good electrical performance can be fabricated without changing or affecting general process condition and process steps. Moreover, the channel region can be designed as multiple channel structure, therefore poly-Si grain size uniformity and grain locations are both improved by width control for each channel region. The present invention is applied for TFT FPD manufacture to fabricate devices with high performance and high value, and more particularly, the number of laser shot used is decreased more effectively for benefiting large size TFT-LCD fabrication.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a flowchart showing a process for fabricating a poly-Si TFT in accordance with the first preferred embodiment of the invention;

FIG. 2A is a cross-sectional schematic diagram showing one part of the process for fabricating a poly-Si TFT in accordance with the first preferred embodiment of the invention;

FIG. 2B is a partial-enlarged top view of lateral crystallization growth structure in poly-Si being formed in accordance with the first preferred embodiment of the invention;

FIG. 3 is a flowchart showing a process for fabricating a poly-Si TFT in accordance with the second preferred embodiment of the invention;

FIGS. 4A and 4B are cross-sectional schematic diagrams showing the process for fabricating a poly-Si TFT in accordance with the second preferred embodiment of the invention;

FIG. 5A is a partial-enlarged top view of the device active region in the poly-Si TFT in accordance with the second preferred embodiment of the invention;

FIG. 5B is a partial-enlarged top view of the device active region in another poly-Si TFT with bad crystallization control; and

FIG. 5C is a partial-enlarged top view of another device active region having a double-channel structure design in accordance with the second preferred embodiment of the invention.

### DETAILED DESCRIPTION OF THE PREFERRED EMBODIMENT

The invention discloses a method of fabricating a poly-Si TFT with large and unifrom grain size. Before laser irradiation is performed, device active regions are first patterned to form amorphous silicon islands. Then, a laser beam with a long pulse is utilized to irradiate the amorphous silicon islands for inducing lateral crystallization growth occurred inside each amorphous silicon island, and a-Si is transformed into poly-Si. Finally, a general TFT manufacturing process is employed directly to fabricate poly-Si TFTs.

### Embodiment 1

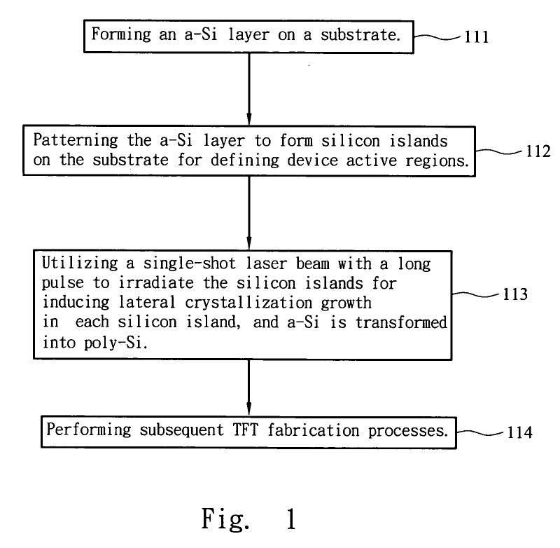

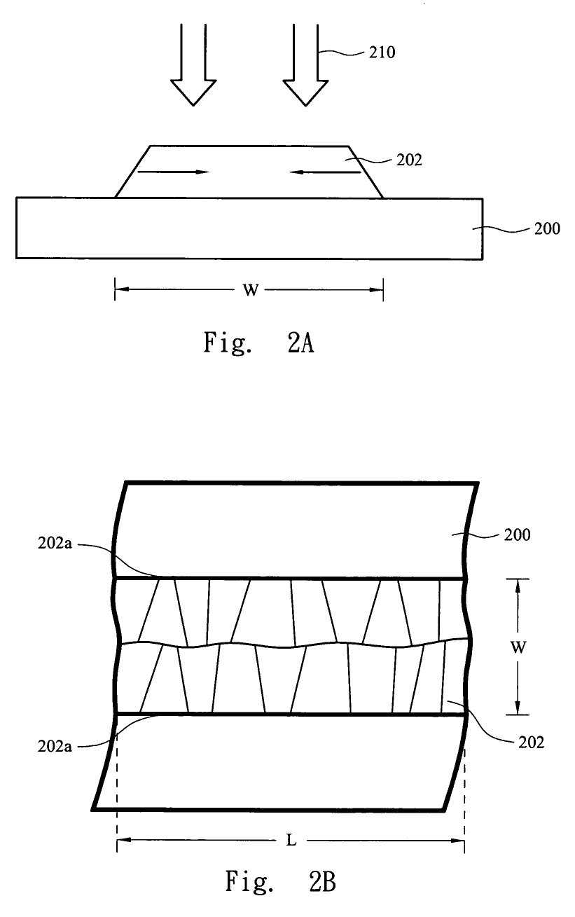

The method of fabricating a poly-Si TFT is disclosed with reference to FIGS. 1, 2A, and 2B. FIG. 1 is a flowchart showing the process for fabricating a poly-Si TFT in accordance with the first embodiment of the present invention; FIG. 2A is a cross-sectional schematic diagram showing one part of the process for fabricating a poly-Si TFT in accordance with the first preferred embodiment of the present invention, and FIG. 2B is a partial-enlarged top view of lateral crystallization growth structure in poly-Si TFT being formed in accordance with the first preferred embodiment of the invention.

First, an a-Si layer formation step 111 in FIG. 1 is performed. Then, step 112 for patterning the a-Si layer to define device active regions is performed, and a-Si islands are thus formed. With reference to FIG. 2A, each amorphous silicon island 202 is formed on a substrate 200 after step 112 in FIG. 1. Wherein, the substrate 200 is a glass, and each amorphous silicon island 202 can be formed by first using plasma enhanced chemical vapor phase deposition (PECVD) or physical vapor deposition (PVD) to form the a-Si layer and followed by a conventional photolithography process to pattern the a-Si layer for defining device active regions in the a-Si layer. Besides, dehydrogenation process can be further performed after forming the a-Si layer to prevent a hydrogen explosion during the subsequent laser irradiation.

Next, a step 113 of laser irradiation in FIG. 1 is performed; as shown in FIG. 2A, a single-shot laser beam 210 with a long pulse is utilized to irradiate each amorphous silicon island 202 for inducing lateral crystallization growth occurred in each amorphous silicon island 202. Wherein, the light source of the laser beam 210 is XeCl ultraviolet (UV) excimer laser pulse.

When the laser beam 210 irradiates each amorphous silicon island 202, each amorphous silicon island 202 is melted, and then each melted amorphous silicon island 202 starts to cool from the edge of long sides toward the inside of each amorphous silicon island 202. Thus, lateral crystallization growth is next occurred from two long sides of each amorphous silicon island 202 and continue toward the inside of each amorphous silicon island 202 after cooling. Therefore, poly-Si with enlarged crystal grains is obtained after laser irradiation step 113 in FIG. 1.

Besides, the present invention finds that using the laser beam 210 with a long pulse to perform the laser irradiation process can lengthen the heating time for melting each amorphous silicon island 202 because of a longer pulse duration. Thus, not only laser energy absorbed in a-Si is increased, but also more heat is able to be transmitted to each amorphous silicon island 202 and the material below a-Si; even uniformity of laser energy distribution inside each amorphous silicon island 202 is further improved. Therefore, lateral crystallization growth inside a-Si is further enhanced for enlarging grain size growth to obtain poly-Si with lateral crystallization growth grains. Moreover, irregular laser energy transmission and poor laser energy distribution are mitigated effectively to enable regular lateral crystallization occurred in each amorphous silicon island 202 so poly-Si formed also has uniform grain size distribution. Thus, just a single-shot laser beam is enough to be utilized in the present invention for achieving good crystallization result so that the frequency or the total number of laser shot used in laser irradiation is decreased effectively for benefiting large size TFT-LCD fabrication.

In a general laser irradiation process, a laser beam with a short pulse, for example, a laser beam with a pulse duration less than 50 ns, is utilized to heat a-Si for crystallization; thus no good lateral crystallization growth can be induced in a-Si, besides, a lot of fine grains are formed easily at the boundary of the silicon island so that poly-Si with irregular grain size is obtained. Crystallization quality is thus reduced, and uniformity of grain size distribution in poly-Si is bad. Even rapid temperature change is easily occurred inside each melted silicon island pattern so that island pattern shrinkage issue is brought out to result in change for the island pattern shape and size when the laser beam with a short pulse is utilized, and device active regions are thus not defined correctly. Then, not only TFT fabrication quality but also device electrical performance is also damaged.

Therefore, the present invention particularly discloses the use of a laser beam with a long pulse in laser irradiation for crystallization. Wherein, a laser beam with a pulse duration of about 100˜300 ns is preferably utilized to irradiate each amorphous silicon island for well keeping the island patterns when lateral crystallization growth is induced inside a-Si and after crystallization.

Normally, the silicon island for defining the device active region is designed as a rectangular strip structure, as shown in FIG. 2A, the cross-sectional view is cut along one short side W of each amorphous silicon island 202. Since the long side (not shown) of each silicon island 202 is obviously longer than the short side W, crystallization occurred in each silicon island 202 is mainly controlled to be appeared at two long sides of each silicon island 202, besides, later crystallization growth is induced from two long sides of each silicon island 202 and then toward the inside of each silicon island 202, as indicated by the arrows in FIG. 2A.

With reference to FIG. 2B simultaneously, polycrystalline structure formed in each island 202 is shown clearly. FIG. 2B is a partial-enlarged top view of lateral crystallization growth structure in poly-Si being formed in accordance with the first preferred embodiment of the invention. Wherein, the length of the long side L of each silicon island 202 is much longer than the short side W (width). Therefore, the lateral crystallization direction in each silicon island 202 is identically from two long sides and then toward the inside of each silicon island 202 so that crystalline structure formed in silicon island 202 has a high grain order.

Finally, referring back to FIG. 1, step 114 is performed to finish the generally subsequent TFT fabrication process after a-Si is transformed into poly-Si. Then, poly-Si TFT fabrication can be completed.

According to the aforementioned method disclosed in the first embodiment, the amorphous silicon island with rectangular strip structure is formed before laser irradiation, and a laser beam with a long pulse is utilized to irradiate the amorphous silicon island so that lateral crystallization growth is induced inside the amorphous silicon island to transform a-Si into poly-Si with lateral growth grains. Besides, grain size in poly-Si formed by applying the present invention can reach as large as several microns. Moreover, the poly-Si with high grain order and uniform grain size distribution is also obtained by the present invention.

Consequently, the first embodiment can be applied directly to fabricate poly-Si TFT devices with good electrical performance without affecting or changing general process condition and process number of general poly-Si TFT fabrication steps.

### Embodiment 2

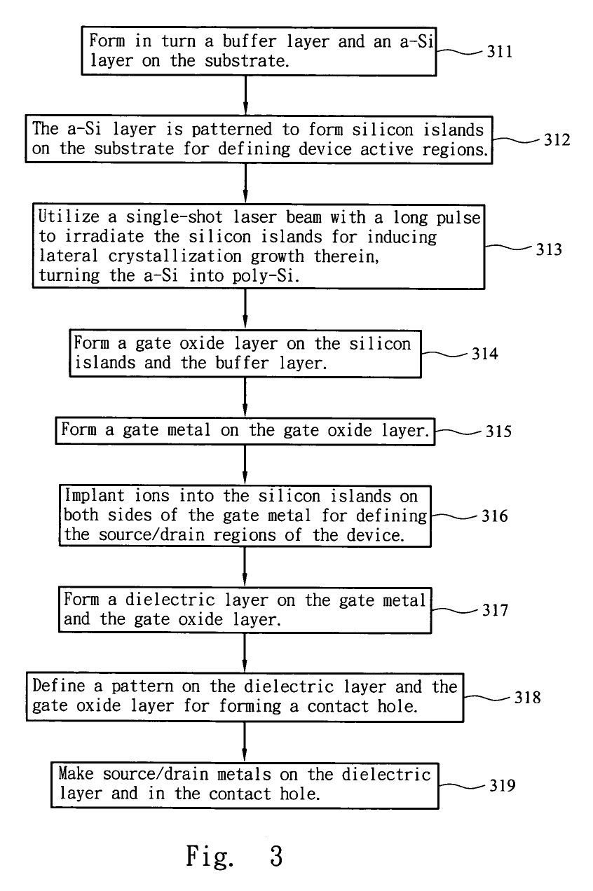

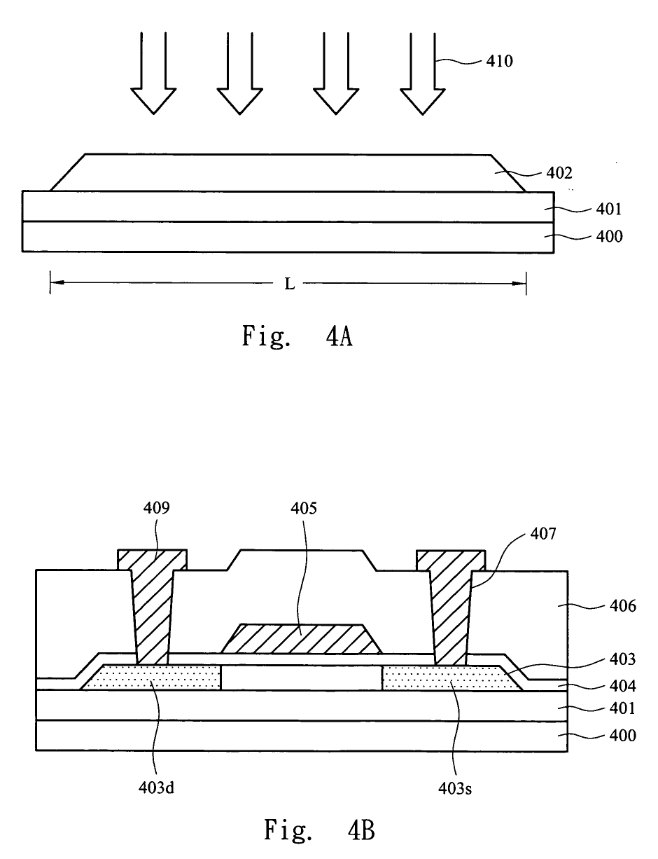

The invention also discloses another method of fabricating a poly-Si TFT. The TFT fabrication with a top gate structure is illustrated in the second preferred embodiment with reference to FIGS. 3, 4A, and 4B. FIG. 3 is a flowchart showing a process for fabricating a poly-Si TFT in accordance with the second preferred embodiment of the invention. FIGS. 4A and 4B are cross-sectional schematic diagrams showing the process for fabricating a poly-Si TFT in accordance with the second preferred embodiment of the invention.

First, a step 311 of forming a buffer layer and an amorphous silicon layer in FIG.3 is performed. With reference to FIG. 4A, a buffer layer 401 and an a-Si layer 402 are formed in turn on a substrate 400. The substrate 400 is glass, and the buffer layer 401 is, for example, a silicon oxide film. Then, a step 312 of patterning for defining device active regions is performed, that is, the a-Si layer 402 is patterned to form a-Si islands on the buffer layer 401. And more particularly, the structure of each a-Si island is designed as a rectangular strip. Besides, dehydrogenation process can be further performed after forming the a-Si layer 402 to prevent a hydrogen explosion during the subsequent laser irradiation.

Next, a step 313 of laser irradiation in FIG. 3 is performed; as shown in FIG. 4A, a single-shot laser beam 410 with a long pulse is utilized to irradiate each a-Si island for inducing lateral crystallization growth occurred in each a-Si island, as described in the first embodiment. Thus, each a-Si island is transformed into a poly-Si island 403 as shown in FIG. 4B. Wherein, each a-Si island has a rectangular strip structure, and the length of the long side L of each a-Si island is much longer than the short side (width). Therefore, the poly-Si island 403 formed after laser irradiation has lateral growth grains with high grain order (as the polycrystalline structure shown in FIG. 2B). The structure shown in FIGS. 4A and 4B are cross-sectional view cut along the long side L of each a-Si island.

After the laser irradiation step 313, the generally subsequent TFT fabrication process is performed when a-Si is transformed into poly-Si. Referring to FIG.3 and FIG. 4B simultaneously, a step 314 of gate oxide formation is performed after the step 313; for example, a gate oxide layer 404 is formed by CVD to cover each poly-Si island 403 and the buffer layer 401. The gate oxide layer 404 is usually a silicon oxide film.

Then, a step 315 in FIG. 3 is performed, a gate metal 405 is formed on the gate oxide layer 404 and on the top of each poly-Si island 403. Wherein, the gate metal 405 is fabricated by PVD and pattern definition process, and the gate metal 405 such as Al, Mo, or MoW is a metal with good conductivity. Next, the gate metal 405 is used as a mask, a step 316 of ion implantation in FIG. 3 is performed to implant ions into each poly-Si island 403 on two sides of the gate metal 405 for defining a source region 403s and a drain region 403d.

After the source/drain regions are defined, a step 317 of forming a dielectric layer in FIG. 3 is performed, that is, a dielectric layer 406 is formed by PECVD to cap the gate metal 405 and the gate oxide layer 404 as shown in FIG. 4B. Then, a step 318 in FIG. 3 is performed to pattern the dielectric layer 406 and the gate oxide layer 404, and contact holes 407 are thus formed to expose the source region 403s and the drain region 403d. Wherein, the dielectric layer 406 is preferably a silicon oxide film.

Finally, a step 319 of making source/drain metals is performed to form the source/drain metals 409 on the dielectric layer 406 and in the contact holes 407 for contacting the source region 403s and the drain region 403d. Material of the source/drain metals 409 is also a metal with good conductivity, such Al, Mo or MoW. Through the aforementioned processes, poly-Si TFT fabrication is finished. The long-pulse laser beam used in the laser irradiation step 313 preferably has a pulse duration of about 100˜300 ns as the first embodiment in order to enhance lateral crystallization growth occurred in each a-Si islands and well keep the profile of island patterns. Therefore, device active regions are defined correctly even though laser irradiation is performed, besides, not only TFT fabrication quality but also device yield are further improved.

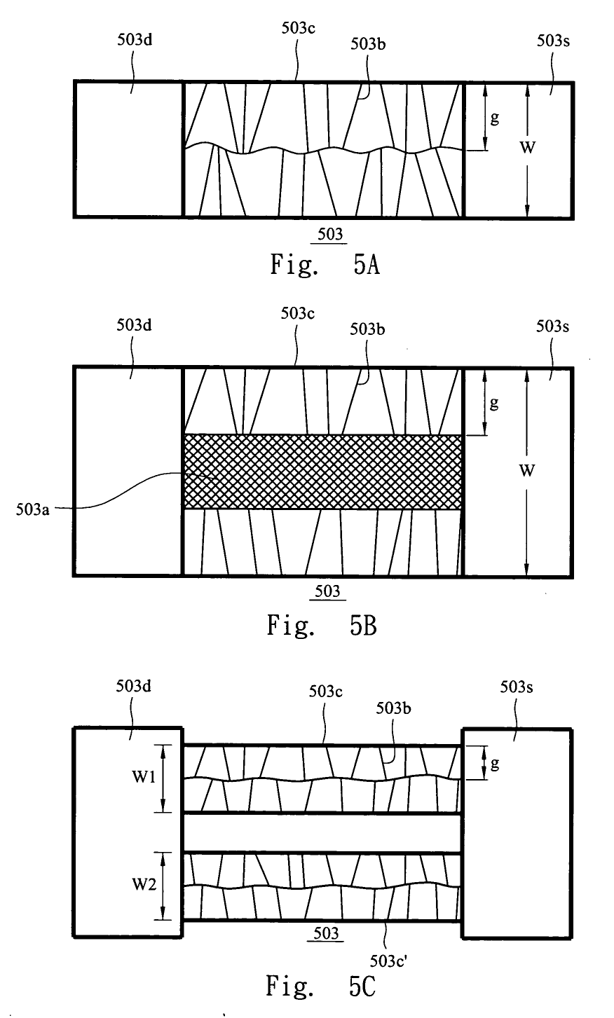

A partial-enlarged top view of the device active region in the poly-Si TFT in accordance with the second preferred embodiment is shown in FIG. 5A. The crystallization growth direction is from two long sides of the silicon island 503 toward the center of the silicon island 503 so that grains in the channel region 503c are located regularly and in a high order. Moreover, the grain size distribution in the channel region 503c is very uniform because of the use of a long pulase laser beam, and the number of grain boundary 503b which carriers have to pass across in each channel region 503c when carries flow from the source region 503s to the drain region 503d is also thus controlled more identically and regularly. Thus, uniformity of each device performance is improved.

Furthermore, if the width of the channel region 503c (i.e. the short side W of the silicon island) is significantly larger than the grain growth length “g” of the lateral crystallization growth, the lateral crystallization result aforementioned is affected and becomes worse, as shown in FIG. 5B. In FIG. 5B, the width of the channel is significantly larger than the grain growth length “g” of the lateral crystallization growth so that lateral growth grains are induced once near the long sides of the channel region 503c, and a lot of fine grains are formed in the center region 503a of the channel region 503c. Thus, good polycrystalline structure in the channel region 503c cannot be obtained probably, even regularity of grains and the uniformity of gain size distribution are also not so good.

In order to avoid the imperfect crystallization result in FIG. 5B, the invention further discloses that the channel region 503c could have a multi-channel structure (as shown in FIG. 5C) in place of the original single-channel structure (as shown in FIG. 5B). More particularly, the channel region 503c in each silicon island can have a plurality of rectangular strip structures.

For example, FIG. 5C shows a partial-enlarged top view of another device active region having a double-channel structure design. Wherein, the first channel region 503c and the second channel region 503c′ have a first channel width W1 and a second channel width W2 respectively. The overall channel width W of the device is the sum of the first channel width W1 and the second channel width W2. Moreover, no matter the first channel width W1 or the second channel width W2 is designed as shorter than a double of the grain growth length “g” of the lateral crystallization growth. (i.e. W1,W2<2 g).

Since the width of each channel is designed as shorter than a double of the grain growth length “g”, only two rows of lateral growth grains are formed and filled with each channel region 503c. Therefore, a poly-Si channel with more uniform and regular grains is obtained, and the number of grain boundary 503b in each channel is almost constant so that the electrical performance uniformity of each poly-Si device is improved for benefiting large size TFT-LCD fabrication.

FIG. 5C just illustrates one example of a poly-Si device with multi-channel structure, and the number of channels in one device region is not limited in the present embodiment. The purpose of multi-channel design is to well control the lateral crystallization growth and decide the crystalline structure inside each channel by division for channel width.

From the aforementioned embodiments, a-Si islands are formed to define device active regions before the laser irradiation process so that a temperature difference region is natively formed inside each a-Si island after laser irradiation for well controlling the location of nucleation sites and inducing the lateral crystallization growth occurred in a-Si. Besides, the laser beam with a long pulse is utilized to further enhance the lateral crystallization growth and make poly-Si fabricated according to the invention has regular and uniform grains.

By employing the present invention, poly-Si TFT devices with good electrical performance are fabricated without changing or affecting general process condition and process number for poly-Si TFT fabrication. Moreover, the laser beam with a long pulse is utilized to lengthen the melting time of a-Si for crystallization and improve the uniformity of laser energy distribution inside each a-Si island. Thus, not only grain size of crystallization is enlarged obviously, but also poly-Si with uniform grain size distribution is obtained. Consequently, even a single shot laser beam can be used in the present invention to achieve a good crystallization result so frequently repeated laser irradiation can be avoided for reducing process cost greatly

Furthermore, the channel region in each device can be designed as a multi-channel structure for improving the grain order and the uniformity of grain size distribution. Therefore, if the present invention is applied for TFT FPD manufacture, poly-Si devices with high performance and high value are fabricated successfully, and more particularly, the frequency or the total number of laser shot used is decreased more effectively for benefiting large size TFT-LCD fabrication.

The present invention is not limited to use in TFT fabrication for flat panel display; other poly-Si TFT devices also can be fabricated by using the present invention to improve production performance. While the present invention has been disclosed with reference to the preferred embodiments of the present invention, it should not be considered as limited thereby. Various possible modifications and alterations by one skilled in the art can be included within the spirit and scope of the present invention, the scope of the invention is determined by the claims that follow.

What is claimed is:

1. A method of fabricating a polycrystalline silicon thin film transistor, comprising the steps of:
forming an amorphous silicon layer on a substrate;
patterning the amorphous silicon layer to form at least one silicon island on the substrate for defining at least one device active region; and
utilizing a single-shot laser beam with a long pulse to irradiate the silicon island for inducing a lateral crystallization growth in the silicon island, and the silicon island is then transformed into a polycrystalline silicon.

2. The method of claim 1, further comprising the step of forming a buffer layer on the substrate before the step of forming the amorphous silicon layer.

3. The method of claim 1, wherein the material of the substrate is glass.

4. The method of claim 1, wherein the silicon island is a rectangular strip.

5. The method of claim 4, wherein the lateral crystallization growth in the silicon island starts from long sides of the silicon island and then continue toward the inside of the silicon island.

6. The method of claim 1, wherein the device active region defined by the silicon island includes a channel region, a source region, and a drain region.

7. The method of claim 6, wherein the channel region in the silicon island is a structure having a single rectangular strip or a plurality of rectangular strips.

8. The method of claim 7, wherein the channel region having the rectangular strips is a multi-channel structure, and the width of each short side of each rectangular strip connecting the source region or the drain region is shorter than a double of a grain growth length of the lateral crystallization growth.

9. The method of claim 1, wherein the single-shot laser beam with the long pulse comprises using an ultraviolet (UV) excimer laser pulse.

10. The method of claim 1, wherein the single-shot laser beam with the long pulse has a pulse duration of about 100˜300 ns.

11. The method of claim 1, further comprising the steps of:
forming a gate oxide layer to cap the silicon island and the substrate;
forming a gate metal on the gate oxide layer and on top of the silicon island;
implanting ions into the silicon island on both sides of the gate metal;
forming a dielectric layer on the gate metal and the gate oxide layer;
patterning the dielectric layer and the gate oxide layer to form a plurality of contact holes for exposing the silicon island; and
forming source/drain metals on the dielectric layer, and each of the source/drain metals is in each of the contact holes for connecting to the silicon island.

12. A method of fabricating a polycrystalline silicon thin film transistor, comprising the steps of:
forming a buffer layer on a substrate;
forming an amorphous silicon layer on the buffer layer;
patterning the amorphous silicon layer to form at least one rectangular strip silicon island on the buffer layer for defining at least one device active region, wherein the rectangular strip silicon island contains a channel region, a source region, and a drain region; and
utilizing a single-shot laser beam with a long pulse to irradiate the rectangular strip silicon island for inducing a lateral crystallization growth in the rectangular strip silicon island; wherein the lateral crystallization growth starts from long sides of the rectangular strip silicon island and then continue toward the inside of the rectangular strip silicon island.

13. The method of claim 12, wherein the material of the substrate is glass.

14. The method of claim 12, wherein the channel region in the rectangular strip silicon island is a structure having a single rectangular strip or a plurality of rectangular strips.

15. The method of claim 14, wherein the channel region having the rectangular strips is a multi-channel structure, and each short side of each rectangular strip connecting the source region or the drain region is shorter than a double of a grain growth length of the lateral crystallization growth.

16. The method of claim 12, wherein the single-shot laser beam with the long pulse comprises using an ultraviolet (UV) excimer laser pulse.

17. The method of claim 12, wherein the single-shot laser beam with the long pulse has a pulse duration of about 100˜300 ns.

18. The method of claim 12, further comprising the steps of:
forming a gate oxide layer to cap the rectangular strip silicon island and the substrate;
forming a gate metal on the gate oxide layer and on top of the channel region of the rectangular strip silicon island;
implanting ions into the rectangular strip silicon island on both sides of the gate metal;
forming a dielectric layer to cover the gate metal and the gate oxide layer;
patterning the dielectric layer and the gate oxide layer to form a plurality of contact holes for exposing the rectangular strip silicon island; and
forming source/drain metals on the dielectric layer, and each of the source/drain metals is in each of the contact holes for connecting to the rectangular strip silicon island.

19. A method of fabricating a polycrystalline silicon thin film transistor device with a top gate structure, comprising the steps of:
forming a buffer layer on a substrate;
forming an amorphous silicon layer on the buffer layer;
patterning the amorphous silicon layer to form at least one rectangular strip silicon island on the buffer layer for defining at least one device active region, wherein the rectangular strip silicon island contains a channel region, a source region, and a drain region;
utilizing a single-shot laser beam with a long pulse to irradiate the rectangular strip silicon island for inducing a lateral crystallization growth in the rectangular strip silicon island, and the rectangular strip silicon island is then transformed into a polycrystalline silicon;
forming a gate oxide layer to cap the rectangular strip silicon island and the substrate;
forming a gate metal on the gate oxide layer and on top of the channel region of the rectangular strip silicon island;
implanting ions into the rectangular strip silicon island on both sides of the gate metal;
forming a dielectric layer to cover the gate metal and the gate oxide layer;
patterning the dielectric layer and the gate oxide layer to form a plurality of contact holes for exposing the rectangular strip silicon island; and
forming source/drain metals on the dielectric layer, and each of the source/drain metals is in each of the contact holes for connecting to the rectangular strip silicon island.

20. The method of claim 19, wherein the single-shot laser beam with the long pulse has a pulse duration of about 100˜300 ns.
